(19) United States
(12) Patent Application Publication
(10) Pub. No.: US 2026/0332128 A1
(43) Pub. Date: Oct. 22, 2026

(54) BANDPASS WITH ALL-PASS FILTER CIRCUIT FOR BEYOND NYQUIST PEAKING

(71) Applicant: Cisco Technology, Inc., San Jose, CA (US)

(72) Inventors: Abhishek Bhat, Santa Clara, CA (US); Ling Zhu, San Diego, CA (US)

(21) Appl. No.: 19/184,425

(22) Filed: Apr. 21, 2025

(51) Int. Cl. H03H 11/04

(52) U.S. Cl. CPC H03H 11/0422

(57) ABSTRACT

A filter circuit is provided comprising an all-pass filter stage, and a bandpass filter stage coupled in parallel with the all-pass filter stage and having a passband. The all-pass filter stage equalizes group delay across a bandwidth of the filter circuit to compensate for group delay distortion introduced by the bandpass filter stage. One use of the filter circuit is to drive a linear driver circuit for an optical modulator in the optical transmitter module.

### TECHNICAL FIELD

The present disclosure relates to optical network equipment.

### BACKGROUND

In optical network equipment, an analog electrical signal is used to drive an optical modulator that outputs a modulated optical signal to be transported via an optical fiber, for example. Traditional re-timed optical transmitters use a 5-6 tap Feed Forward Equalizer (FFE) before a Mach-Zehnder Interferometer (MZI) optical modulator driver using clocks and flipflops. For linear drive non-retimed applications, a traditional discrete-time FFE cannot be used. Implementing an equivalent analog FFE for linear drive is a possible solution. However, an analog FFE using passive inductor-capacitor (LC) ladders can be area and power-hungry. An analog FFE using an active FFE also consumes area and power. T-coils for bandwidth extension consume area and active transconductance amplifiers (Gm's) for a multi-tap FFE consume power.

A stage that can replicate the response of a discrete or analog 5-tap FFE with low area and power can be useful for linear drive applications. An analog FFE adaptation is not easy to implement because the parameters, like tap delay, can vary across process and need calibration. Also, a least mean squares (LMS) loop is needed in an analog FFE to sample and adjust the weights.

### BRIEF DESCRIPTION OF THE DRAWINGS

FIG. 1 illustrates a block of a transmitter that includes a host Application Specific Integrated Circuit (ASIC) and an optical transmitter module that includes a bandpass with all-pass filter circuit according to an example embodiment.

FIG. 2A is a schematic diagram of the bandpass with all-pass filter circuit according to an example embodiment.

FIG. 2B is a schematic diagram of the bandpass with all-pass filter circuit according to another example embodiment.

FIG. 3 is a schematic diagram of a transconductance amplifier that may be used for the various transconductance amplifiers of the bandpass with all-pass filter circuit, according to an example embodiment.

FIG. 4A illustrates plots of group delay and phase shift versus frequency of the bandpass filter stage of the bandpass with all-pass filter circuit, according to an example embodiment.

FIG. 4B illustrates a plot of magnitude response versus frequency of the bandpass filter stage of the bandpass with all-pass filter circuit, according to an example embodiment.

FIG. 5A illustrates a plot representing overall or total magnitude response for the bandpass with all-pass filter circuit, according to an example embodiment.

FIG. 5B illustrates a plot of group delay versus frequency for bandpass filter stage and a plot for group delay versus frequency of the bandpass with all-pass filter circuit, according to an example embodiment.

FIG. 6A illustrates a plot of magnitude response for an ideal 5-tap analog feed forward equalizer (FFE) compared with a plot of magnitude response for a bandpass with all-pass filter circuit, according to an example embodiment.

FIG. 6B illustrates a plot of group delay response for simulations of a bandpass with all-pass filter circuit presented herein, and compared with a plot of group delay response for an ideal 5-tap analog FFE according to an example embodiment.

FIG. 7 illustrates plots showing a comparison of total response from a data source at a host device to an input of a linear driver in the transmitter path shown in FIG. 1 for an ideal analog 5-tap FFE and simulations of a bandpass with all-pass filter circuit presented herein, according to an example embodiment.

FIG. 8 illustrates plots of magnitude response of a bandpass with all-pass filter circuit presented herein and showing how a peaking magnitude may be adjusted to accommodate different types of optical channels, according to an example embodiment.

FIG. 9A illustrates a screenshot from a simulation showing an eye diagram of signals at the output of the continuous time linear equalizer of the transmitter shown in FIG. 1.

FIG. 9B illustrates a screen shot from a simulation showing an eye diagram of signals at the output of the bandpass with all-pass filter circuit presented herein, according to an example embodiment.

FIG. 10 is a flow chart depicting a method for filtering signals in a transmitter with a bandpass with all-pass filter circuit, according to an example embodiment.

### DESCRIPTION OF EXAMPLE EMBODIMENTS

### Overview

Briefly, in one embodiment, a filter circuit is provided comprising an all-pass filter stage, and a bandpass filter stage coupled in parallel with the all-pass filter stage and having a passband that is programmable. The all-pass filter stage equalizes group delay across a bandwidth of the filter circuit to compensate for group delay distortion introduced by the bandpass filter stage. One use of the filter circuit is to drive a linear driver circuit for an optical modulator in the optical transmitter module.

In another embodiment, an apparatus is provided comprising an all-pass filter stage that includes a variable capacitor having a capacitance that is adjustable to configure a group delay associated with the all-pass filter stage; and a bandpass filter stage coupled in parallel with the all-pass filter stage and having a passband, wherein the bandpass filter stage includes a variable capacitor having a capacitance that is adjustable to vary a programmable peaking frequency associated with the passband.

In another embodiment, a method is provided comprising: obtaining a differential analog signal at a filter circuit in an optical transmitter module; directing the differential analog signal to an all-pass filter stage of the filter circuit and to a bandpass filter stage that is coupled in parallel with the all-pass filter stage; filtering the differential analog signal with the all-pass filter stage to equalize group delay across a bandwidth to compensate for group delay distortion introduced by the bandpass filter stage, to produce all-pass differential output currents; filtering the differential analog signal with the bandpass filter stage that has a passband to produce bandpass differential output currents; and adding the all-pass differential output currents to the bandpass differential output currents at differential output nodes of the filter circuit to drive a linear driver circuit for an optical modulator in the optical transmitter module.

### EXAMPLE EMBODIMENTS

In a typical transmitter that uses a retiming clock, a feed forward equalizer (FFE) is often used and can work well due to the presence of a retiming clock. Precise delays can be generated without bandwidth degradation when there is a retiming clock available. An optical transmitter module includes a continuous time linear equalizer (CTLE) to receive an analog output from a host Application Specific Integrated Circuit (ASIC). The CTLE can equalize some of the bands in the input signals, but a 5-6 tap FFE can perform additional equalization to achieve a flat magnitude response at the optical modulator output.

However, linear non-retimed pluggable optics (LPO) have been found to greatly reduce power consumption of an optical module A non-retimed pluggable optics module use a low power front end with good linearity. Traditionally, an analog FFE can provide equalization beyond the peaking range of a CTLE, and thus opens up the eye diagram of the signal. This comes at a cost because an analog FFE can use a lot of area in an integrated circuit, and can also consume a lot of power. For example, an analog T/2 spaced FFE consumes significant area, is bandwidth limited, and consumes a substantial amount of power.

More specifically, traditional retimed transmitters use a 5-6 tap FFE, with clocks and flip-flops before coupling signals to an optical modulator (e.g., a Mach-Zehnder optical modulator). For linear drive non-retimed applications, a traditional discrete-time FFE cannot be used. On the other hand, implementing an equivalent analog FFE for linear drive is a possible solution. However, an analog FFE uses passive inductor-capacitor (LC) ladders that are area and power-hungry, as explained above. An analog active FFE also consumes area and power. T-coils for bandwidth extension can be used, but they consume area and active transconductance amplifiers for a multi-tap FFE consume power. An analog FFE adaptation is not easy to implement as the parameters, such as tap delay, can vary across process and involve calibration. Furthermore, a least mean square (LMS) loop is used to sample and adjust the weights of the analog FFE. A filter circuit that can replicate the response of a discrete or analog 5-tap FFE with low area and power can be useful for linear drive applications.

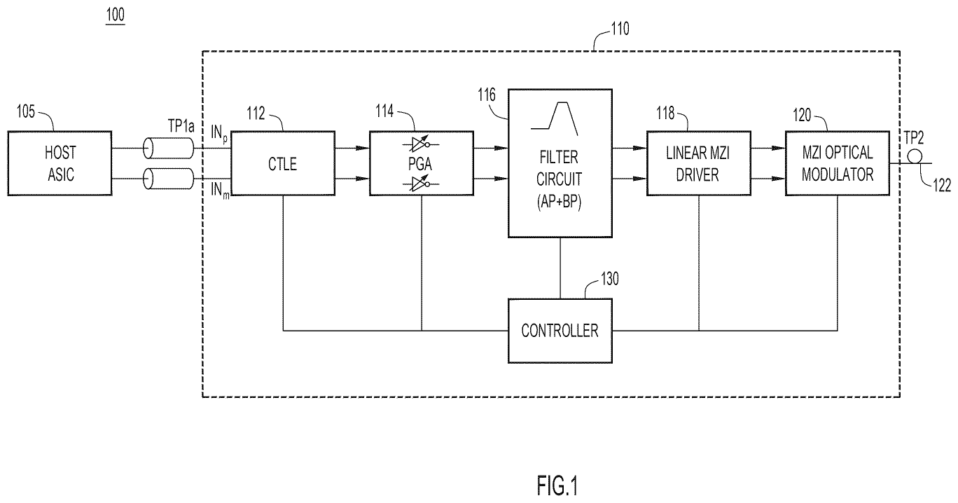

Reference is now first made to FIG. 1. FIG. 1 shows a block diagram of transmitter 100 that includes a host Application Specific Integrated Circuit (ASIC) 105 and an optical transmitter module 110. The host ASIC 105 outputs differential transmit signal INₚ and INₘ. A CTLE 112 is coupled to receive as input the differential transmit signal INₚ and INₘ. The CTLE 112 may be implemented using complementary metal oxide silicon (CMOS) techniques having a low frequency (LF) and high frequency (HF) gain. A programmable gain amplifier (PGA) 114 is coupled to the CTLE 112, and a filter circuit 116 is connected to the output of the PGA 114. The filter circuit 116 is a bandpass with all-pass filter circuit according to embodiments presented herein. A linear Mach-Zehnder Interferometer (MZI) driver circuit 118 is connected to the output of the filter circuit 116. The linear MZI driver circuit 118 is coupled to an MZI optical modulator 120 that modulates an optical signal onto a fiber 122 for transmission. The differential inputs to the MZI optical modulator 120 may have a bandwidth of up to 30-35 GHz. While FIG. 1 shows a linear MZI driver circuit and an MZI optical modulator, this is only an example. The filter circuit 116 may be used with any optical modulator, such as an electro-absorption-modulated laser (EML) and a vertical-cavity surface-emitting laser (VSEL), etc.

The optical transmitter module 110 may further include a controller 130, such as a microprocessor or microcontroller. The controller 130 may be connected to the analog circuits in the optical transmitter module 110 to capture performance measurement data as well as to program or configure one or more parameters of the analog circuits, including, as described below, the transconductances of variable transconductance amplifiers and capacitances of variable capacitors of the filter circuit 116. Transconductance amplifiers are also known as transconductors. In one example, during initial power up, the controller 130 of the optical transmitter module 110 does training/learning about the optical channel of the optical fiber 122, and can change parameters of the analog circuits in the optical transmitter module 110. The controller 130 analyzes measurements made about the channel and operation performance, and makes those parameter adjustments of the analog circuits.

In at least one embodiment, the controller 130 may be, or may include, at least one hardware processor configured to execute various tasks, operations and/or functions. Controller 130 (e.g., a hardware processor) can execute any type of instructions associated with data to achieve the operations detailed herein. In one example, controller 130 can transform an element or an article (e.g., data, information) from one state or thing to another state or thing. Any of potential processing elements, microprocessors, digital signal processor, baseband signal processor, modem, PHY, controllers, systems, managers, logic, and/or machines described herein can be construed as being encompassed within the broad term ‘processor’.

In at least one embodiment, there is a memory associated with, or included with controller 130. The memory may be configured to store data, information, software, and/or instructions associated with the operations described herein that may be performed by the controller 130.

The filter circuit 116 comprises an all-pass filter stage and a parallel bandpass filter stage for linear drive applications to perform channel equalization and transmitter pre-emphasis. In this regard, the filter circuit 116 is also referred to herein as a bandpass with all-pass filter circuit 116. This filter circuit 116 can replace a traditional 5-6 tap analog FFE. The bandpass filter stage has a passband that has one or more parameters that are programmable, such as a programmable peak frequency beyond the Nyquist frequency of the optical transmitter, without significant group delay distortion, unlike a CTLE. The filter circuit 116 can have a programmable peak magnitude and a programmable group delay, as well as a programmable peaking slope, which is not possible with a conventional CTLE. The filter circuit 116 can save as much as 3-times in silicon area when compared to a 5-tap analog FFE, and can consume at least 2-times less power than a 5-tap analog FFE. Further details of the filter circuit 116 are described below.

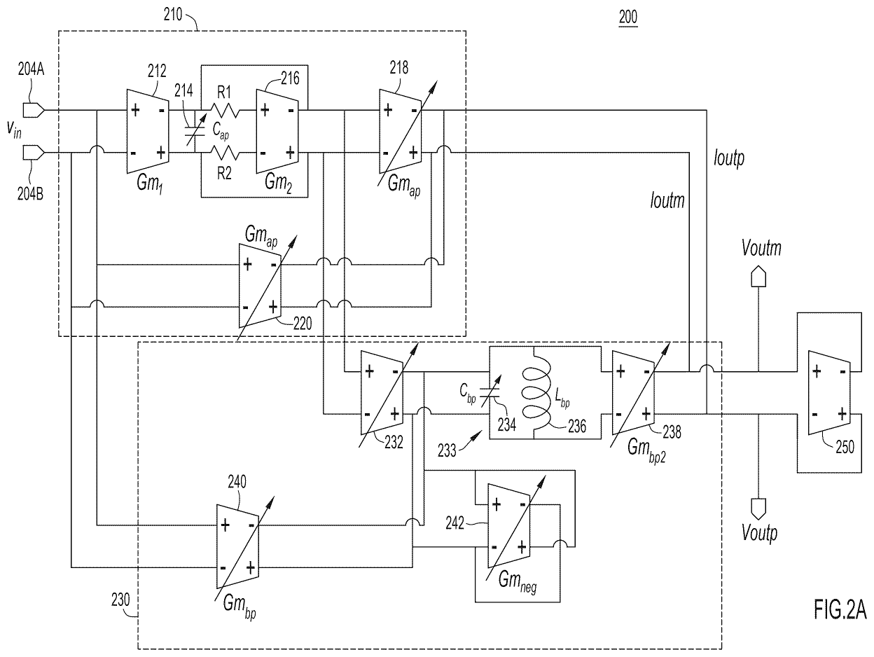

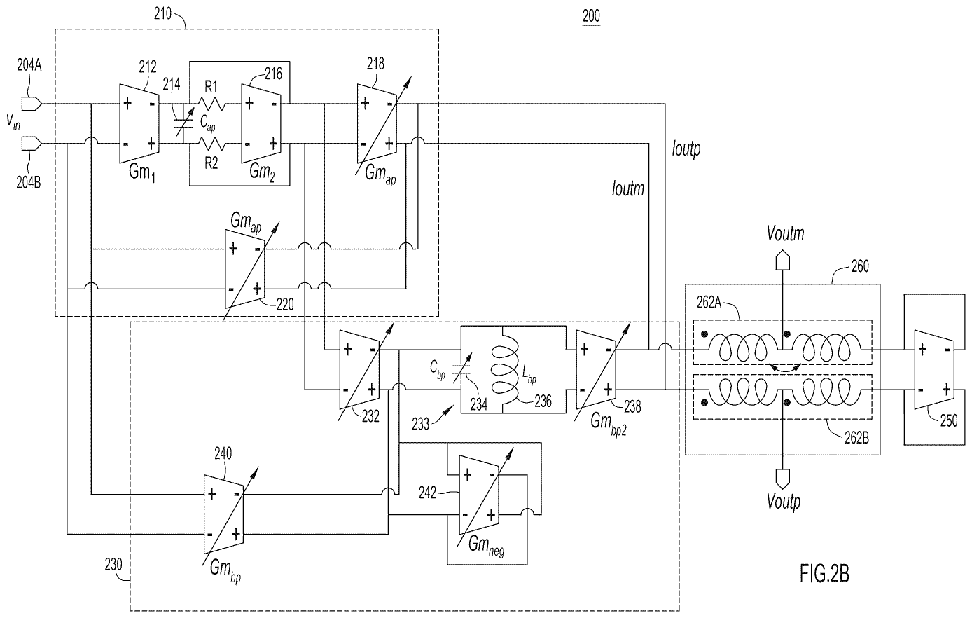

Reference is now made to FIG. 2A. FIG. 2A illustrates a schematic diagram of a filter circuit 200 that may be used as the bandpass with all-pass filter circuit 116 shown in FIG. 1. The filter circuit 200 comprises differential input nodes 204A and 204B to which a differential input shown as Vin is applied. The filter circuit 200 comprises an all-pass filter stage 210 and a bandpass filter stage 230. The bandpass filter stage has a passband that is programmable in that it may have a programmable peaking frequency as well as a programmable peaking magnitude, as described in more detail below.

In one embodiment, the all-pass filter stage 210 may have a first path and a second path, parallel to the first path. In the first path, the all-pass filter stage 210 may include a first (differential) transconductance amplifier 212 coupled to the input Vin, a variable capacitor 214 coupled across differential outputs of the first transconductance amplifier 212, a second transconductance amplifier 216, and a third transconductance amplifier 218 that has a variable transconductance gain (Gmₐₚ). The first transconductance amplifier 212 may have a fixed gain, denoted Gₘ₁, and the second transconductance amplifier 216 may have a fixed gain, denoted Gₘ₂. The variable capacitor 214 is connected across the differential outputs of the first transconductance amplifier 212, and the differential outputs of the first transconductance amplifier 212 are coupled to the inputs to the second transconductance amplifier 216 by resistors R1 and R2. The differential outputs of the second transconductance amplifier 216 are also connected back to opposite nodes of the variable capacitor 214, as shown in FIG. 2A.

The second path of the all-pass filter stage 210 comprises a fourth transconductance amplifier 220 that has a variable transconductance gain Gmₐₚ. The fourth transconductance amplifier 220 receives as input differential inputs Vin and generates differential outputs (currents) that are coupled to respective differential outputs of the third transconductance amplifier 218, to add differential output currents to respective differential output currents of the third transconductance amplifier 218. The resulting differential currents are Ioutp and Ioutm and may be referred to as all-pass differential output currents. The transfer response from the differential input voltage Vin to the all-pass differential output currents Ioutp and Ioutm is an all-pass response (flat magnitude across a wide frequency range, but with some group delay/phase shift).

The bandpass filter stage 230 is connected in parallel with the all-pass filter stage 210, and may comprise a first path and a second path. The first path of the bandpass filter stage 230 may include a first (variable) transconductance amplifier 232, an inductor-capacitor (LC) tank circuit 233 comprising a variable capacitor 234 connected in parallel with an inductor 236, and a second (variable) transconductance amplifier 238. The variable capacitor 234 has a variable capacitance C_{bp} used to set the peaking frequency associated with a passband of the bandpass filter stage 230. The first transconductance amplifier 232 obtains its differential inputs from the differential outputs of the second transconductance amplifier 216 of the all-pass filter stage 210. That is, the differential outputs of the second transconductance amplifier 216 of the all-pass filter stage 210 are connected to the differential inputs of the first transconductance amplifier of the bandpass filter stage 230. The differential outputs of the first transconductance amplifier 232 are coupled across the capacitor 234, and the differential inputs to the second transconductance amplifier 238 correspond to the voltages across the inductor 236. In other words, the inductor-capacitor tank circuit 233 is connected between differential outputs of the first transconductance amplifier 232 and differential inputs of the second transconductance amplifier 238. Differential outputs (differential currents) of the second transconductance amplifier are connected to differential outputs of the third transconductance amplifier 218 of the all-pass filter stage 210. Thus, differential output currents from the second transconductance amplifier 238 are added, at filter circuit differential output nodes, to the all-pass differential output currents Ioutp and Ioutm from the all-pass filter stage 210and to provide filter circuit differential output voltages Voutp and Voutm.

The second path of the bandpass filter stage 230 may comprise a third (variable) transconductance amplifier 240 and a fourth (variable) transconductance amplifier 242. The third transconductance amplifier 240 receives Vin as input, and generates differential outputs that are connected to nodes at respective differential outputs of the first transconductance amplifier 232 and to nodes at respective differential inputs of the fourth transconductance amplifier 242. In addition, the outputs of the fourth transconductance amplifier 242 are connected back to its inputs (positive output connects to positive input, and negative output connects to negative input).

As mentioned above, the differential outputs of the filter circuit 200 are at nodes of the filter circuit for filter circuit differential output voltages Voutm and Voutp, which correspond to the nodes at which the currents Ioutp and Ioutm are added to the negative and positive outputs of the second transconductance amplifier 238. The bandpass filter stage 230 provides the high frequency peaking. The bandpass filter stage 230 takes part of the voltage from the all-pass filter stage 210 (via the connection between the differential outputs of the second transconductance amplifier 216 of the all-pass filter stage and the differential inputs of the first transconductance amplifier 232 of the bandpass filter stage 230) and the input voltage, and sums them up into the inductor-capacitor tank circuit 233, which performs the bandpass filtering that is then amplified by the second transconductance amplifier 238 of the bandpass filter stage 230.

There is a transconductance amplifier 250 at the output of the filter circuit 200. The transconductance amplifier has its differential outputs connected back to its differential inputs. The differential outputs of the transconductance amplifier 250 are connected in a negative feedback arrangement to its differential inputs. This sets the direct current (DC) bias point of the output nodes and also acts like a resistor of value 1/Gm, where Gm is the differential transconductance gain of 250. This is similar to the transconductance amplifier 216 in the all-pass filter stage 210. As a result, the output differential current of the filter circuit 200 flows through the resistance 1/Gm to produce differential output voltages Voutp and Voutm.

The variable capacitor 214, with variable capacitance Cₐₚ, sets the group delay of the all-pass filter stage 210. The group delay equation for all pass filter stage 210 is given by Gd=

$$\frac{2 τ}{1 + {ω}^{2} {τ}^{2}} ,$$

where

$$τ = \frac{{C}_{a p}}{G m 2} .$$

The transconductance amplifier 216 with input/output connected in where negative feedback looks like a resistance of value 1/Gₘ₂. The group delay from input Vin to the output of the 216 depends on the ratio Cₐₚ/Gm2. The higher the variable capacitance Cₐₚ the higher the group delay of the all-pass filter stage 210. Thus, the group delay of the all-pass filter stage 210 can be changed by changing the Cₐₚ or Gm2. Changing Gm2 can also change the magnitude response. It is therefore desirable to change only Cₐₚ. It is noted that this group delay is a function of frequency, which reduces with frequency.

As explained above, the variable capacitor 234 is used to program the peaking frequency (FLC) associated with the passband of the bandpass filter stage, according to the equation:

FLC=1/(2π√L_{bp}C_{bp})

The programmable gains of the transconductance amplifiers 218 and 220 in the all-pass filter stage 210 and the programmable gains of the transconductance amplifiers 232, 238 and 240 in the bandpass filter stage 230 may be used to set the programmable peaking magnitude associated with the passband of the bandpass filter stage 230, according to the equation:

Programmable peaking magnitude (dB)=20 log(Gm_{bp}R_{bp}Gm_{bp2}/Gmₐₚ), where R_{bp} is the equivalent parallel resistance of the inductor-capacitor tank circuit in the bandpass filter stage 230.

In one example, the transconductance gain Gm₁ of transconductance amplifier 212 and the transconductance gain Gm₂ of transconductance amplifier 216 may be set such that Gm₁/Gm₂=2. In addition, the transconductance gain Gm_{neg} of the transconductance amplifier 242 in the bandpass filter stage 230 may be used to adjust the peaking slope or quality factor, Qₚₑₐₖ, associated with the passband of the bandpass filter stage 230. Gm_{neg} is formed by connecting the positive and negative inputs of transconductance amplifier 242 with respective outputs, so that the transconductance amplifier 242 is in positive feedback. This makes it look like a negative resistance 1/Gm_{neg}.

$$Qpeak = \frac{1}{( G {m}_{l o s s} - G {m}_{n e g} ) {ω}_{0} {L}_{b p}} ,$$

where ω0 is the resonance frequency of the LC tank circuit 233, which is same as the peaking frequency of the bandpass stage. Gmloss is the equivalent loss transconductance of the LC tank circuit 233 due to the loss in the capacitor and inductor. Hence, increasing Gm_{neg} increases the quality factor Qpeak and thereby increases the slope of the peaking near resonance of the LC tank circuit 233. Gm_{neg} should always be less than Gmₗₒₛₛ for stability.

Turning now to FIG. 2B, a diagram is shown of the filter circuit 200, similar to that of FIG. 2A, but further including a T-coil 260. The T-coil 260 comprises two coupled inductor pairs 262A and 262B, one pair for each differential signal path. The T-coil 260 can help improve the bandwidth of the filter circuit 200 to drive large capacitance loads, like an MZI driver circuit 118 (shown in FIG. 1).

The filter circuit 200 provides gain beyond the Nyquist frequency at resonance of the inductor-capacitor tank circuit 233 of the bandpass filter stage 230. The resonance of the inductor-capacitor tank circuit 233 can cause phase distortion (group delay), which increases and peaks at the peaking frequency FLC. The all-pass filter stage 210 has a group delay similar to that of a low pass filter, that is, a constant group delay at low frequency and drops as the frequency increases that can provide sufficient low frequency group delay to compensate for the group delay introduced by the bandpass filter stage 230 near peaking frequency. The group delay response of the filter circuit 200 is substantially the same as an analog 5-tap FFE, and does not reduce signal swing unlike a CTLE. That is, the filter circuit 200 amplifies only the higher frequencies, resulting in better signal-to-noise ratio (SNR).

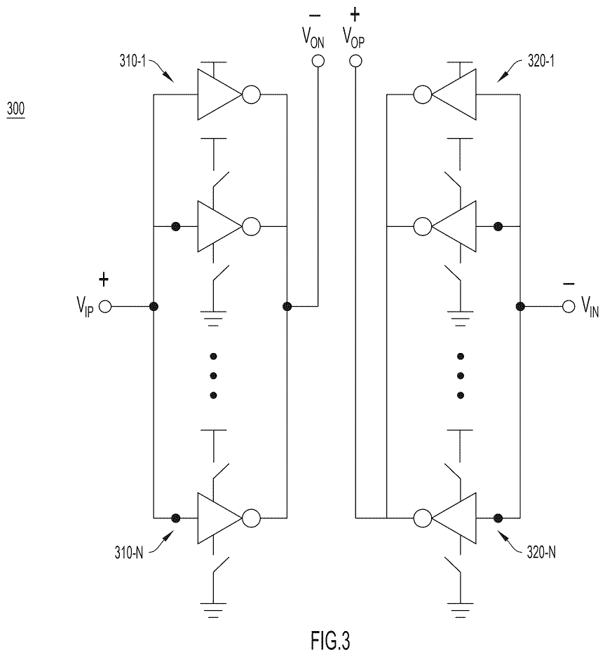

Turning now to FIG. 3, a schematic diagram is shown of an example circuit structure that may be used for any of the programmable transconductance amplifiers of the filter circuits shown in FIGS. 2A and 2B. A programmable transconductance amplifier 300 may be built from a plurality of inverters for each signal path of the differential signals paths. For the positive signal path that receives an input voltage VIP, there are a plurality of inverters 310-1 to 310-N arranged in parallel with each other, and selectively turned on/connected such that the more inverters that are selected/switched on into the path, the greater the transconductance applied from the input VIP to the output VON. Similarly, there are a plurality of inverters 320-1 to 320-N arranged in parallel with each other, and selectively turned on/connected such that the more inverters that are selected/switched on into the path, the greater the transconductance applied from the input V_{IN} to the output V_{OP}. Thus, the programmable nature of the transconductance amplifiers may be achieved by turning on and off some of a plurality of inverters. At one extreme, when all of the inverters are turned on/selected, then a maximum transconductance Gm us achieved, and when all of the inverters are turned off/not selected, then a minimum transconductance Gm is achieved.

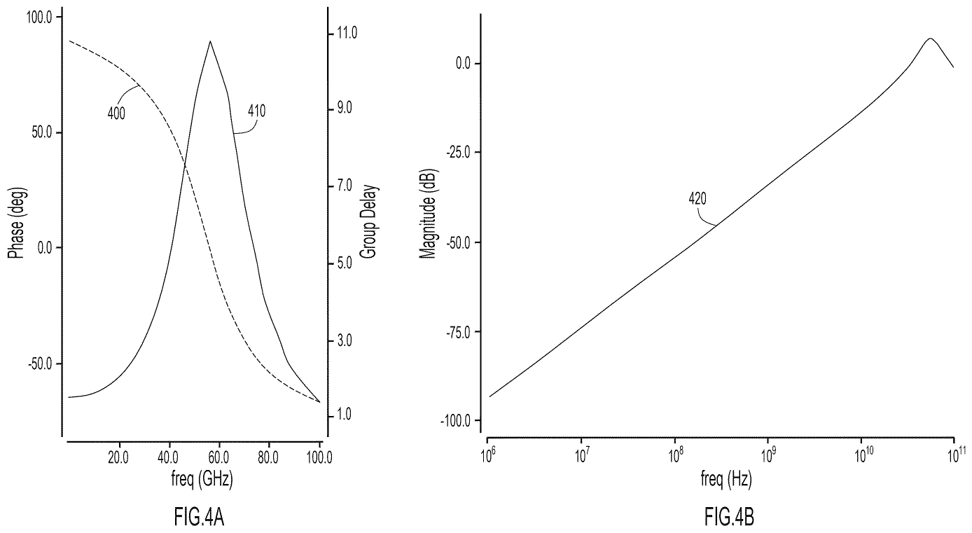

FIGS. 4A and 4B illustrate plots depicting operation of the bandpass filter stage 230 of the filter circuit 200. FIG. 4A illustrates plots of group delay and phase shift versus frequency and FIG. 4B illustrates a plot of magnitude response versus frequency. In the plots of FIGS. 4A and 4B, the programmable peaking frequency associated with the passband of the bandpass filter stage 230 is 56 GHz, as an example. As shown in FIG. 4A, the plot 400 is for phase and the plot 410 is for group delay. Plot 410 shows that group delay is greatest at the frequency where the LC tank circuit peaks at resonance. Thus, for example, at 56 GHz, the group delay is 10 picoseconds (ps) and the group delay at low frequencies is approximately zero. In general, plot 410 shows the group delay is not constant and that is not desirable, particularly for a broadband signal (DC to 28 GHZ, for example). It is to be noted that the peaking frequency of the filter circuit 200 is programmable, as mentioned above, and need not always be 2-times the Nyquist frequency.

FIG. 4B shows a plot 420 of magnitude response of the bandpass filter stage 230. The plot 420 shows that the magnitude is highest at the peaking frequency of 56 GHz, in this example. The all-pass filter stage 210, connected in parallel with the bandpass filter stage 230, equalizes group delay across frequencies. In particularly, the all-pass filter stage 210 provides a group delay that reduces with frequency, which compensates for the group delay of the bandpass filter stage 230 that increases with frequency, as shown in FIG. 4A.

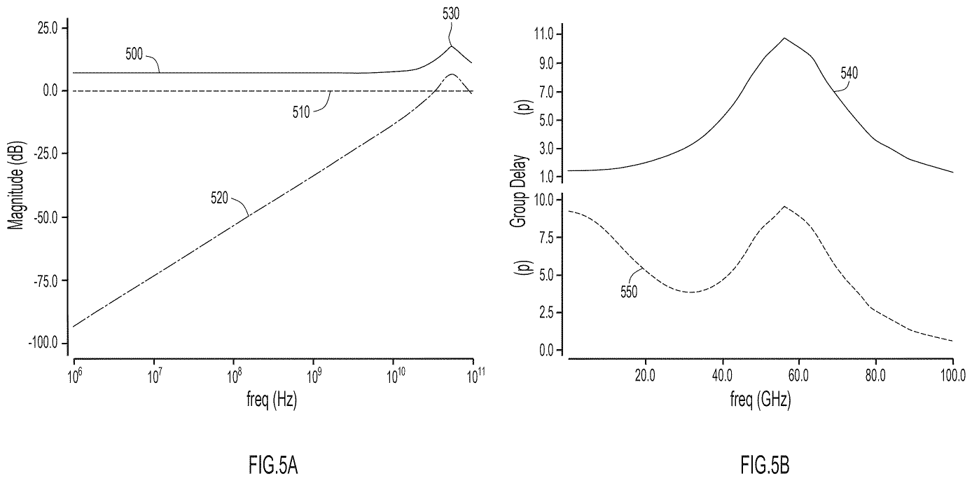

Turning now to FIGS. 5A and 5B, plots are shown for simulation performance results of the filter circuit 200 that includes an all-pass filter stage 210 and bandpass filter stage 230. FIG. 5A shows a plot 500 representing an overall or total magnitude response for the filter circuit 200 that is a summation of the magnitude response for the all-pass filter stage 210, represented by plot 510, and the magnitude response for the bandpass filter stage 230, represented by plot 520. Plot 500 shows that the magnitude response for the filter circuit 200 is flat until the desired peaking frequency, as shown at 530, which in this example is 56 GHz, where the desired bandpass filtering effects are to occur.

FIG. 5B illustrates a plot 540 of group delay versus frequency for bandpass filter stage 230 and a plot 550 is for group delay versus frequency of the filter circuit 200. FIG. 5B shows that the all-pass filter stage equalizes the group delay across frequency by providing a group delay that reduces with frequency unlike the group delay of the bandpass filter stage which increases with frequency.

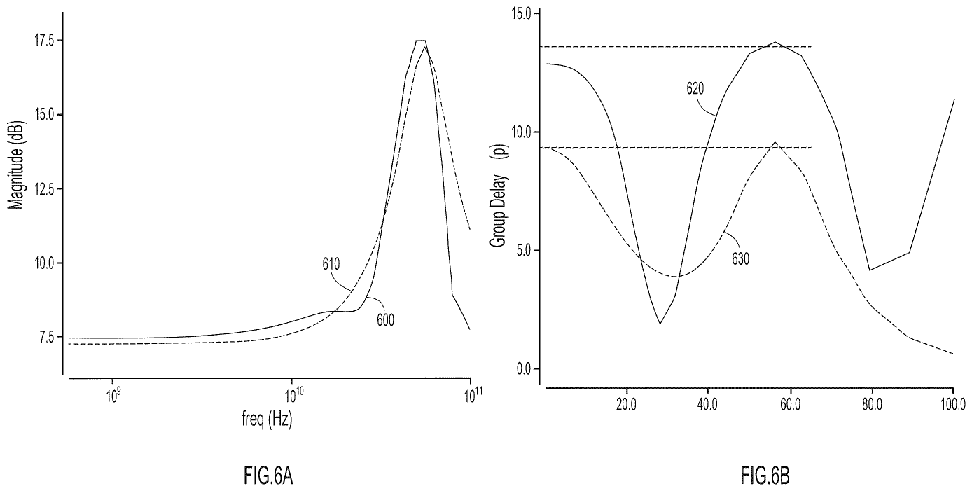

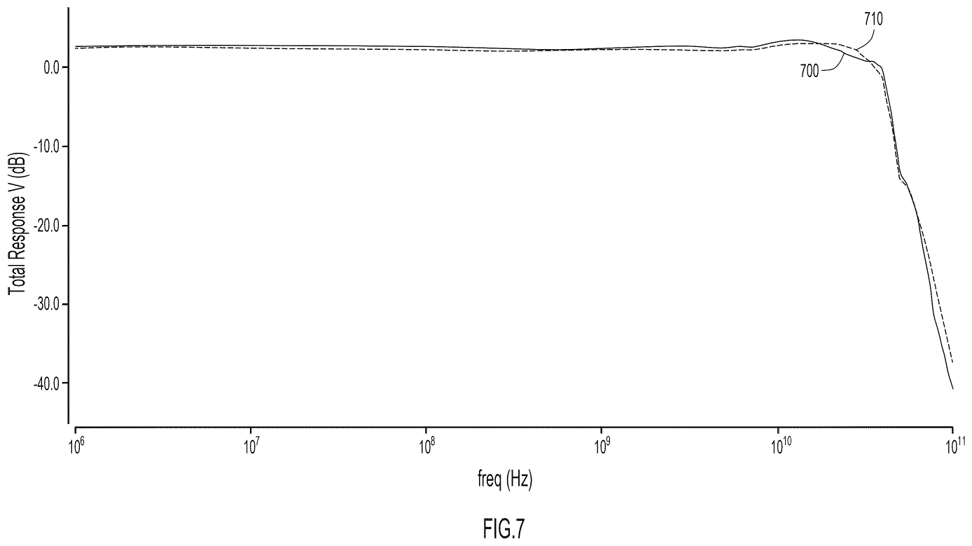

FIGS. 6A and 6B show plots comparing the performance the filter circuit 200 with an ideal 5-tap analog FFE. FIG. 6A illustrates a plot 600 for magnitude response for an ideal 5-tap analog FFE, and plot 610 shows the magnitude response for simulations of the filter circuit 200. As can be seen in FIG. 6A, the magnitude response for the filter circuit 200 very closely matches the magnitude response of an analog 5-tap FFE. Similarly, FIG. 6B illustrates a plot 620 for group delay for an ideal 5-tap analog FFE and plot 630 is for group delay for the filter circuit 200. Again, the group delay plot 630 for the filter circuit closely matches that of the ideal 5-tap FFE. It is noted that the absolute group delay is not of concern, rather it is the group delay change with frequency, that is, the shape of the curve, which is of concern. The shape of the plot 630 representing the group delay of the filter circuit 200 is close to the shape of the plot 620 for an analog 5-tap FFE.

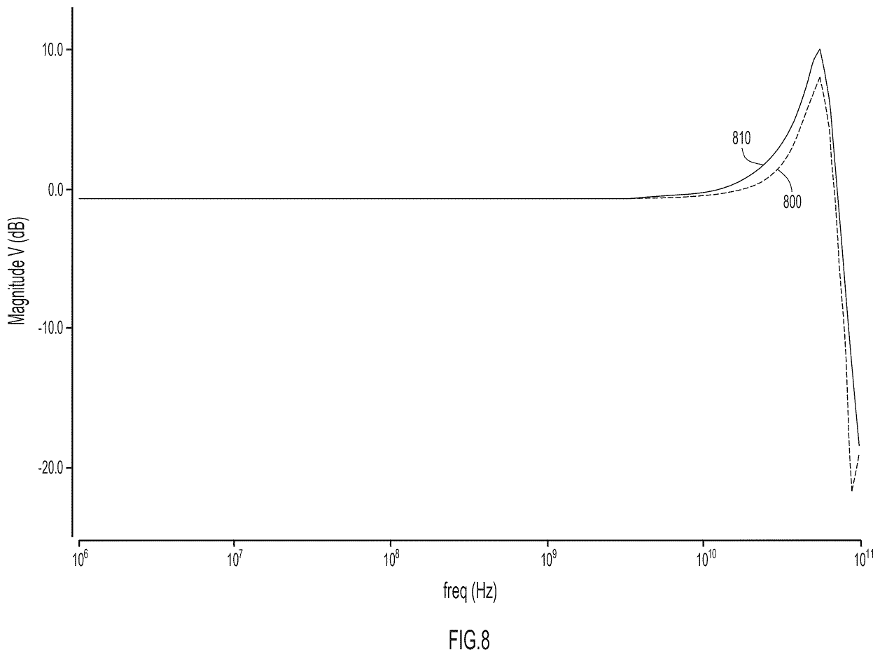

Turning now to FIG. 7, plots are showing comparing a total/overall response (based on input from a host ASIC to the output of the filter circuit of the transmitter 100 shown in FIG. 1). Plot 700 is the total response when an ideal analog 5-tap FFE is used and plot 710 is a plot for the total/overall response when the filter circuit 200 is used in place of an analog 5-tap FFE. Thus, FIG. 7 shows that the total response for a broadband signal (36 GHz) is essentially the same when the filter circuit 200 is used. The filter circuit 200 compensates for any loss in the channel and for the bandwidth limitations of the linear MZI driver circuit 118 shown in FIG. 1.

The filter circuit 200 can achieve an “eye” diagram that is the same or better than that which can be achieved by an ideal analog 5-tap FFE. However, the filter circuit 200 consumes much less power and occupies 3-times less area than an analog 5-tap FFE.

Turning now to FIG. 8, plots are shown to illustrate how the peaking magnitude of the filter circuit 200 can be adjusted to accommodate different types of electrical channels from host ASIC to the transmitter module. Plot 800 is for a 2″ channel that operates with a lower peaking magnitude (8.0819 dB at 56 GHZ) whereas plot 810 is for a 10″ channel that operates higher peaking magnitude (10.083 dB at 56 GHz). The filter circuit 200 can adjust the peaking magnitude by reducing the transconductance (Gm) in the bandpass filter stage 230.

Peaking magnitude (height of the peaks shown in FIG. 8) can be adjusted with the following parameters of the filter circuit 200. First, the programmable transconductance gain (Gm) values for the transconductance amplifiers in the filter circuit 200 can be adjusted. For example, larger Gm values of the programmable transconductance amplifiers 232, 238, 240 and 242 (shown in FIG. 1) in the bandpass filter stage 230 increases the peaking magnitude (associated with the passband) of the filter circuit 200. Conversely, reducing the Gm values of these programmable amplifiers in the bandpass filter stage 230 reduces the peaking magnitude (associated with the passband) of the filter circuit 200. In addition, larger Gm values of the programmable transconductance amplifiers 218 and 220 in the all-pass filter stage 210 increases the all-pass gain, thereby reducing the peaking magnitude of the filter circuit 200. Conversely, reducing the Gm values of the programmable transconductance amplifiers 218 and 220 in the all-pass filter stage 210 decreases the all-pass gain, thereby increasing the peaking magnitude of the filter circuit 200.

As explained above, other adjustments can be made by the filter circuit 200. Adjusting the capacitance of variable capacitor 234 of the inductor-capacitor tank circuit 233 of the bandpass filter stage 230 can vary the peaking frequency of the peaking magnitude. In addition, adjusting the capacitance of variable capacitor 214 in the all-pass filter stage 210 can vary the group delay of the all-pass filter stage 210.

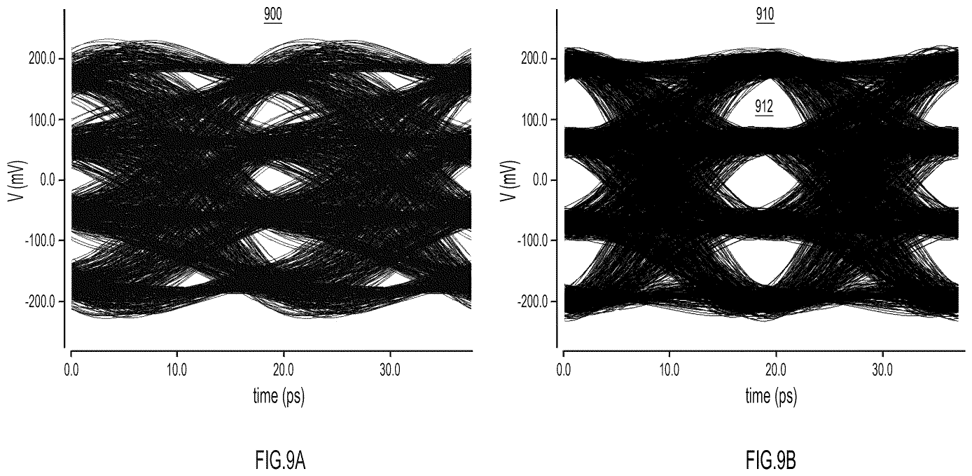

Reference is now made to FIGS. 9A and 9B. FIG. 9A shows a screenshot from a simulation showing an eye diagram 900 of the signals at the output of the CTLE 112 of the transmitter shown in FIG. 1, for a 2″ channel. FIG. 9B shows a screenshot from a simulation showing an eye diagram 910 of the signals at the output of the filter circuit 200. Notably, the openings of the eye diagram 910 are wider and more defined, as shown at reference numeral 912, than that of eye diagram 900 at the output of the CTLE, prior to processing the filter circuit 200.

As explained above, the filter circuit 200 can replace a 5-tap analog FFE, and in so doing, use much less area and consume much less power. As an example, a 5-tap analog FFE that employs a traveling wave topology has an LC ladder arrangement of 24 inductors or T-coils (100 pico Henries (pH)×24), each with an impedance of approximately 50 ohms. Large pre-drivers are required to drive doubly terminated transmission lines. This consumes a significant amount of area, and can require significant power to drive the inductors and compensate for LC ladder losses. In addition, an LC ladder can limit bandwidth and increase losses. By contrast, the filter circuit 200 presented herein can employ one inductor, and the transconductance amplifiers need not drive 50 ohms, and thus can be much lower power. The bandwidth of the filter circuit 200 can be higher because there is no cascading of inductors involved.

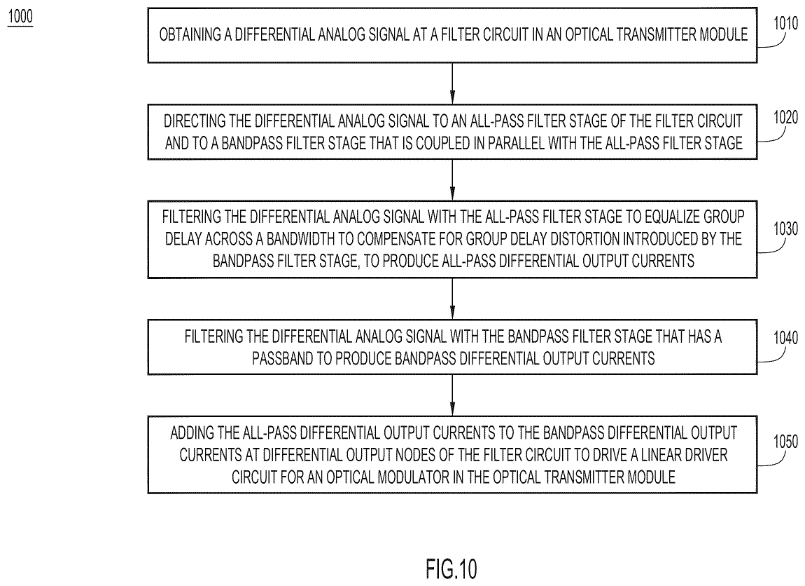

Turning now to FIG. 10, a flow chart is shown for a method 1000 according to an example embodiment. The method 1000 includes, at step 1010, obtaining a differential analog signal at a filter circuit in an optical transmitter module. At step 1020, the method 1000 involves directing the differential analog signal to an all-pass filter stage of the filter circuit and to a bandpass filter stage that is coupled in parallel with the all-pass filter stage. At step 1030, the method 1000 involves filtering the differential analog signal with the all-pass filter stage to equalize group delay across a bandwidth to compensate for group delay distortion introduced by the bandpass filter stage, to produce all-pass differential output currents. At step 1040, the method 1000 involves filtering the differential analog signal with the bandpass filter stage that has a passband to produce bandpass differential output currents. At step 1050, the method 1000 involves adding the all-pass differential output currents to the bandpass differential output currents at differential output nodes of the filter circuit and passing resulting differential currents through an output resistance to generate a differential output voltage to drive a linear driver circuit for an optical modulator in the optical transmitter module.

In some aspects, the techniques described herein relate to a filter circuit including: an all-pass filter stage; and a bandpass filter stage coupled in parallel with the all-pass filter stage and having a passband that is programmable, wherein the all-pass filter stage equalizes group delay across a bandwidth of the filter circuit to compensate for group delay distortion introduced by the bandpass filter stage.

In some aspects, the techniques described herein relate to a filter circuit, wherein the all-pass filter stage has a variable capacitor having a capacitance that is adjustable to configure a group delay associated with the all-pass filter stage.

In some aspects, the techniques described herein relate to a filter circuit, wherein the bandpass filter stage is configured to have a programmable peaking frequency associated with the passband.

In some aspects, the techniques described herein relate to a filter circuit, wherein the bandpass filter stage includes a variable capacitor having a capacitance that is adjustable to vary the programmable peaking frequency.

In some aspects, the techniques described herein relate to a filter circuit, wherein one or both of the all-pass filter stage and the bandpass filter stage each has one or more variable transconductance amplifiers with an adjustable transconductance gain to adjust a peaking magnitude associated with the passband.

In some aspects, the techniques described herein relate to a filter circuit, wherein the bandpass filter stage is configured to have a programmable peaking magnitude associated with the passband.

In some aspects, the techniques described herein relate to a filter circuit, wherein the bandpass filter stage has at least one variable transconductance amplifier having an adjustable transconductance gain to program a peaking slope associated with the passband.

In some aspects, the techniques described herein relate to a filter circuit, wherein the bandpass filter stage includes an inductor-capacitor tank circuit including a variable capacitor connected in parallel with an inductor, wherein a capacitance of the variable capacitor is adjustable for a programmable peaking frequency associated with the passband.

In some aspects, the techniques described herein relate to a filter circuit, further including filter circuit differential input nodes and filter circuit differential output nodes, wherein the all-pass filter stage includes: a first path and a second path coupled in parallel to the first path, wherein the first path includes a first transconductance amplifier having differential inputs coupled to the filter circuit differential input nodes, a second transconductance amplifier coupled to differential outputs of the first transconductance amplifier, a third transconductance amplifier coupled to differential outputs of the second transconductance amplifier, and a variable capacitor connected across the differential outputs of the first transconductance amplifier, and wherein the second path includes a fourth transconductance amplifier having differential inputs coupled to the differential inputs of the filter circuit and differential outputs coupled to respective differential outputs of the third transconductance amplifier to add differential output currents to respective differential output currents of the third transconductance amplifier to produce all-pass differential output currents provided to the filter circuit differential output nodes, wherein one or both of the third transconductance amplifier and the fourth transconductance amplifier having a variable transconductance gain.

In some aspects, the techniques described herein relate to a filter circuit, wherein the bandpass filter stage includes: a first path and a second path, wherein the first path the bandpass filter stage includes a first transconductance amplifier, an inductor-capacitor tank circuit including a variable capacitor connected in parallel with an inductor, a second transconductance amplifier, and a third transconductance amplifier, wherein the first transconductance amplifier has differential inputs connected to the differential outputs of the second transconductance amplifier of the all-pass filter stage, the inductor-capacitor tank circuit is connected between differential outputs of the first transconductance amplifier and differential inputs of the second transconductance amplifier, wherein differential outputs of the second transconductance amplifier are connected to differential outputs of the third transconductance amplifier of the all-pass filter stage such that differential output currents from the second transconductance amplifier of the first path of the bandpass filter stage are added, at the filter circuit differential output nodes, to the all-pass differential output currents from the all-pass filter stage and to provide filter circuit differential output voltages at the filter circuit differential output nodes, wherein the second path of the bandpass filter stage includes a third transconductance amplifier and a fourth transconductance amplifier, the third transconductance amplifier having differential inputs coupled to the filter circuit differential input nodes and generating differential outputs connected to nodes at respective differential outputs of the first transconductance amplifier of the first path of the bandpass filter stage and to nodes at respective differential inputs of the fourth transconductance amplifier of the second path of the bandpass filter stage, wherein outputs of the fourth transconductance amplifier are connected back to differential inputs of the fourth transconductance amplifier, and wherein one or more of the first transconductance amplifier, the second transconductance amplifier, the third transconductance amplifier and the fourth transconductance amplifier have a variable transconductance gain.

In some aspects, the techniques described herein relate to a filter circuit, wherein a capacitance of the variable capacitor in the inductor-capacitor tank circuit is used to set a peaking frequency of the passband of the bandpass filter stage.

In some aspects, the techniques described herein relate to a filter circuit, wherein a capacitance of the variable capacitor in the first path of the all-pass filter stage is used to set a group delay associated with the all-pass filter stage.

In some aspects, the techniques described herein relate to a filter circuit, wherein the variable transconductance gain of one or more of the first transconductance amplifier, the second transconductance amplifier, the third transconductance amplifier and the fourth transconductance amplifier of the bandpass filter stage is used to adjust a peaking magnitude associated with the passband.

In some aspects, the techniques described herein relate to a filter circuit, wherein the variable transconductance gain of the third transconductance amplifier and/or the fourth transconductance amplifier is used to adjust a peaking magnitude associated with the passband.

In some aspects, the techniques described herein relate to a filter circuit, further including a T-coil connected between differential outputs of the filter circuit.

In some aspects, the techniques described herein relate to an apparatus including: an all-pass filter stage that includes a variable capacitor having a capacitance that is adjustable to configure a group delay associated with the all-pass filter stage; and a bandpass filter stage coupled in parallel with the all-pass filter stage and having a passband, wherein the bandpass filter stage includes a variable capacitor having a capacitance that is adjustable to vary a programmable peaking frequency associated with the passband.

In some aspects, the techniques described herein relate to an apparatus, wherein one or both of the all-pass filter stage and the bandpass filter stage each has one or more variable transconductance amplifiers with an adjustable transconductance gain to adjust a peaking magnitude associated with the passband.

In some aspects, the techniques described herein relate to an apparatus, wherein the bandpass filter stage has at least one variable transconductance amplifier having an adjustable transconductance gain to program a peaking slope associated with the passband.

In some aspects, the techniques described herein relate to a method including: obtaining a differential analog signal at a filter circuit in an optical transmitter module; directing the differential analog signal to an all-pass filter stage of the filter circuit and to a bandpass filter stage that is coupled in parallel with the all-pass filter stage; filtering the differential analog signal with the all-pass filter stage to equalize group delay across a bandwidth to compensate for group delay distortion introduced by the bandpass filter stage, to produce all-pass differential output currents; filtering the differential analog signal with the bandpass filter stage that has a passband to produce bandpass differential output currents; and adding the all-pass differential output currents to the bandpass differential output currents at differential output nodes of the filter circuit to drive a linear driver circuit for an optical modulator in the optical transmitter module.

In some aspects, the techniques described herein relate to a method, further including adjusting a capacitance of a variable capacitor of the all-pass filter stage to configure a group delay associated with the all-pass filter stage.

In some aspects, the techniques described herein relate to a method, further including adjusting a capacitance of a variable capacitor in an inductor capacitor tank circuit of the bandpass filter stage to adjust a programmable peaking frequency associated with a passband.

In some aspects, the techniques described herein relate to an optical transmitter including: a continuous time linear equalizer configured to receive as input differential transmit signals from a host device and provide equalized differential outputs; a programmable gain amplifier coupled to receive as input the equalized differential outputs of the continuous time linear equalizer, and to amplify the equalized differential outputs to produce amplified differential outputs; a filter circuit configured to receive as input the amplified differential outputs of the programmable gain amplifier, wherein the filter circuit includes an all-pass filter stage and a bandpass filter stage coupled in parallel with the all-pass filter stage and having a passband, wherein the all-pass filter stage equalizes group delay across a bandwidth of the filter circuit, and wherein the filter circuit outputs filtered amplified differential outputs; and a linear driver circuit configured to receive as input the filtered amplified differential outputs from the filter circuit and to generate differential drive signals for an optical modulator.

In various embodiments, any entity or apparatus as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term ‘memory element’. Data/information being tracked and/or sent to one or more entities as discussed herein could be provided in any database, table, register, list, cache, storage, and/or storage structure: all of which can be referenced at any suitable timeframe. Any such storage options may also be included within the broad term ‘memory element’ as used herein.

Note that in certain example implementations, operations as set forth herein may be implemented by logic encoded in one or more tangible media that is capable of storing instructions and/or digital information and may be inclusive of non-transitory tangible media and/or non-transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, memory element(s) and/or storage can store data, software, code, instructions (e.g., processor instructions), logic, parameters, combinations thereof, and/or the like used for operations described herein. This includes memory element(s) and/or storage being able to store data, software, code, instructions (e.g., processor instructions), logic, parameters, combinations thereof, or the like that are executed to carry out operations in accordance with teachings of the present disclosure.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

### Variations and Implementations

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi6®), IEEE 802.16 (e.g., Worldwide Interoperability for Microwave Access (WiMAX)), Radio-Frequency Identification (RFID), Near Field Communication (NFC), Bluetooth™, mm.wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

In various example implementations, any entity or apparatus for various embodiments described herein can encompass network elements (which can include virtualized network elements, functions, etc.) such as, for example, network appliances, forwarders, routers, servers, switches, gateways, bridges, loadbalancers, firewalls, processors, modules, radio receivers/transmitters, or any other suitable device, component, element, or object operable to exchange information that facilitates or otherwise helps to facilitate various operations in a network environment as described for various embodiments herein. Note that with the examples provided herein, interaction may be described in terms of one, two, three, or four entities. However, this has been done for purposes of clarity, simplicity and example only. The examples provided should not limit the scope or inhibit the broad teachings of systems, networks, etc. described herein as potentially applied to a myriad of other architectures.

Communications in a network environment can be referred to herein as ‘messages’, ‘messaging’, ‘signaling’, ‘data’, ‘content’, ‘objects’, ‘requests’, ‘queries’, ‘responses’, ‘replies’, etc. which may be inclusive of packets. As referred to herein and in the claims, the term ‘packet’ may be used in a generic sense to include packets, frames, segments, datagrams, and/or any other generic units that may be used to transmit communications in a network environment. Generally, a packet is a formatted unit of data that can contain control or routing information (e.g., source and destination address, source and destination port, etc.) and data, which is also sometimes referred to as a ‘payload’, ‘data payload’, and variations thereof. In some embodiments, control or routing information, management information, or the like can be included in packet fields, such as within header(s) and/or trailer(s) of packets. Internet Protocol (IP) addresses discussed herein and in the claims can include any IP version 4 (IPv4) and/or IP version 6 (IPv6) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of can be represented using the’ (s)′ nomenclature (e.g., one or more element(s)).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

1. A filter circuit comprising:
an all-pass filter stage; and
a bandpass filter stage coupled in parallel with the all-pass filter stage and having a passband that is programmable,
wherein the all-pass filter stage equalizes group delay across a bandwidth of the filter circuit to compensate for group delay distortion introduced by the bandpass filter stage.

2. The filter circuit of claim 1, wherein the all-pass filter stage has a variable capacitor having a capacitance that is adjustable to configure a group delay associated with the all-pass filter stage.

3. The filter circuit of claim 1, wherein the bandpass filter stage is configured to have a programmable peaking frequency associated with the passband.

4. The filter circuit of claim 3, wherein the bandpass filter stage comprises a variable capacitor having a capacitance that is adjustable to vary the programmable peaking frequency.

5. The filter circuit of claim 3, wherein one or both of the all-pass filter stage and the bandpass filter stage each has one or more variable transconductance amplifiers with an adjustable transconductance gain to adjust a peaking magnitude associated with the passband.

6. The filter circuit of claim 3, wherein the bandpass filter stage is configured to have a programmable peaking magnitude associated with the passband.

7. The filter circuit of claim 3, wherein the bandpass filter stage has at least one variable transconductance amplifier having an adjustable transconductance gain to program a peaking slope associated with the passband.

8. The filter circuit of claim 1, wherein the bandpass filter stage comprises an inductor-capacitor tank circuit comprising a variable capacitor connected in parallel with an inductor, wherein a capacitance of the variable capacitor is adjustable for a programmable peaking frequency associated with the passband.

9. The filter circuit of claim 1, further comprising filter circuit differential input nodes and filter circuit differential output nodes, wherein the all-pass filter stage comprises:
a first path and a second path coupled in parallel to the first path,
wherein the first path comprises a first transconductance amplifier having differential inputs coupled to the filter circuit differential input nodes, a second transconductance amplifier coupled to differential outputs of the first transconductance amplifier, a third transconductance amplifier coupled to differential outputs of the second transconductance amplifier, and a variable capacitor connected across the differential outputs of the first transconductance amplifier, and
wherein the second path comprises a fourth transconductance amplifier having differential inputs coupled to the differential inputs of the filter circuit and differential outputs coupled to respective differential outputs of the third transconductance amplifier to add differential output currents to respective differential output currents of the third transconductance amplifier to produce all-pass differential output currents provided to the filter circuit differential output nodes,
wherein one or both of the third transconductance amplifier and the fourth transconductance amplifier have a variable transconductance gain.

10. The filter circuit of claim 9, wherein the bandpass filter stage comprises:
a first path and a second path,
wherein the first path of the bandpass filter stage comprises a first transconductance amplifier, an inductor-capacitor tank circuit comprising a variable capacitor connected in parallel with an inductor, a second transconductance amplifier, and a third transconductance amplifier, wherein the first transconductance amplifier has differential inputs connected to the differential outputs of the second transconductance amplifier of the all-pass filter stage, the inductor-capacitor tank circuit is connected between differential outputs of the first transconductance amplifier and differential inputs of the second transconductance amplifier, wherein differential outputs of the second transconductance amplifier are connected to differential outputs of the third transconductance amplifier of the all-pass filter stage such that differential output currents from the second transconductance amplifier of the first path of the bandpass filter stage are added, at the filter circuit differential output nodes, to the all-pass differential output currents from the all-pass filter stage and to provide filter circuit differential output voltages at the filter circuit differential output nodes,
wherein the second path of the bandpass filter stage comprises a third transconductance amplifier and a fourth transconductance amplifier, the third transconductance amplifier having differential inputs coupled to the filter circuit differential input nodes and generating differential outputs connected to nodes at respective differential outputs of the first transconductance amplifier of the first path of the bandpass filter stage and to nodes at respective differential inputs of the fourth transconductance amplifier of the second path of the bandpass filter stage, wherein outputs of the fourth transconductance amplifier are connected back to differential inputs of the fourth transconductance amplifier, and
wherein one or more of the first transconductance amplifier, the second transconductance amplifier, the third transconductance amplifier and the fourth transconductance amplifier have a variable transconductance gain.

11. The filter circuit of claim 10, wherein a capacitance of the variable capacitor in the inductor-capacitor tank circuit is used to set a peaking frequency of the passband of the bandpass filter stage.

12. The filter circuit of claim 10, wherein a capacitance of the variable capacitor in the first path of the all-pass filter stage is used to set a group delay associated with the all-pass filter stage.

13. The filter circuit of claim 10, wherein the variable transconductance gain of one or more of the first transconductance amplifier, the second transconductance amplifier, the third transconductance amplifier and the fourth transconductance amplifier of the bandpass filter stage is used to adjust a peaking magnitude associated with the passband.

14. The filter circuit of claim 10, wherein the variable transconductance gain of the third transconductance amplifier and/or the fourth transconductance amplifier is used to adjust a peaking magnitude associated with the passband.

15. The filter circuit of claim 1, further comprising a T-coil connected between differential outputs of the filter circuit.

16. An apparatus comprising:
an all-pass filter stage that includes a variable capacitor having a capacitance that is adjustable to configure a group delay associated with the all-pass filter stage; and
a bandpass filter stage coupled in parallel with the all-pass filter stage and having a passband, wherein the bandpass filter stage includes a variable capacitor having a capacitance that is adjustable to vary a programmable peaking frequency associated with the passband.

17. The apparatus of claim 16, wherein one or both of the all-pass filter stage and the bandpass filter stage each has one or more variable transconductance amplifiers with an adjustable transconductance gain to adjust a peaking magnitude associated with the passband.

18. The apparatus of claim 16, wherein the bandpass filter stage has at least one variable transconductance amplifier having an adjustable transconductance gain to program a peaking slope associated with the passband.

19. A method comprising:
obtaining a differential analog signal at a filter circuit in an optical transmitter module;
directing the differential analog signal to an all-pass filter stage of the filter circuit and to a bandpass filter stage that is coupled in parallel with the all-pass filter stage;
filtering the differential analog signal with the all-pass filter stage to equalize group delay across a bandwidth to compensate for group delay distortion introduced by the bandpass filter stage, to produce all-pass differential output currents;
filtering the differential analog signal with the bandpass filter stage that has a passband to produce bandpass differential output currents; and
adding the all-pass differential output currents to the bandpass differential output currents at differential output nodes of the filter circuit to drive a linear driver circuit for an optical modulator in the optical transmitter module.

20. The method of claim 19, further comprising adjusting a capacitance of a variable capacitor of the all-pass filter stage to configure a group delay associated with the all-pass filter stage.
